(19) United States
(12) Patent Application Publication
(10) Pub. No.: US 2021/0072318 A1
(43) Pub. Date: Mar. 11, 2021

(54) DETERMINING A MOTOR ABNORMALITY BASED ON A DRIVE COMMAND PROVIDED TO THE MOTOR AND A CURRENT AMPLITUDE OF POWER PROVIDED TO THE MOTOR

(71) Applicant: HP PRINTING KOREA CO. LTD., Gyeonggi-do (KR)

(72) Inventors: In PARK, Suwon-si (KR); Byung Sun MIN, Yongin-si (KR)

(73) Assignee: HP PRINTING KOREA CO., LTD., Gyeonngi-do (KR)

(21) Appl. No.: 16/645,322

(22) PCT Filed: Feb. 27, 2018
(86) PCT No.: PCT/KR2018/002403

§ 371 Date: Mar. 6, 2020

(30) Foreign Application Priority Data
Sep. 25, 2017 (KR) 10-2017-0123424

(51) Int. Cl. G01R 31/34; B65H 3/06; G03G 15/00

(52) U.S. Cl. CPC G01R 31/343; B65H 3/06; G03G 15/50; G03G 15/55; B65H 2403/92; B65H 2511/52; B65H 2515/702; B65H 2515/704; G03G 15/80

(57) ABSTRACT

An engine portion to perform an image forming job, a motor to drive the engine portion, and a drive circuit to provide power to the motor are included in an image forming apparatus. The drive circuit includes a sensor that detects a current amplitude of the power provided to the motor. A processor of the image forming apparatus provides a drive command to the motor and determines whether the motor is abnormal based on the drive command and a current amplitude detected after the drive command is provided.

### BACKGROUND ART

Disclosed herein is an image forming apparatus capable of identifying a motor abnormality within the image forming apparatus based on a drive command to drive a motor and a current amplitude of power provided to the motor. An image forming apparatus is an apparatus which performs generation, printing, reception, and transmission of image data, and representative examples thereof may be a printer, a copy machine, a facsimile, and a multifunction peripheral (MFP) in which functions of at least two of the above-described devices are combined.

Such an image forming apparatus is provided with a drive portion for performing various functions, such as moving a printing paper or feeding a printing paper, and such a drive portion is operated by a motor.

In particular, in recent years, as the option unit that performs various functions can be attached to the image forming apparatus, the number of motors that can be used in the image forming apparatus is increasing.

### DISCLOSURE OF INVENTION

### Brief Description of Drawings

The above and/or other aspects will become more apparent by reference to example embodiments which are illustrated in the appended drawings. Understanding that these drawings depict only example embodiments and are not therefore to be considered to be limiting of the scope of the disclosure, the principles herein are described and explained with additional specificity and detail via the use of the accompanying drawings, in which:

FIG. 1 is a block diagram illustrating a brief configuration of the image forming apparatus, according to an example embodiment;

FIG. 2 is a block diagram illustrating an example configuration of the image forming apparatus, according to an example embodiment;

FIG. 3 is a diagram according to an example embodiment of an engine portion of FIG. 1;

FIG. 4 illustrates a configuration of a paper transferring portion;

FIG. 6 is a circuit diagram of the drive circuit of FIG. 1;

FIG. 7 illustrates a sensor unit;

FIGS. 8, 9, 10, and 11 are diagrams illustrating a method for determining an abnormality based on a drive current detected by a sensor; and

FIG. 12 is a flowchart illustrating a method for image forming, according to an example embodiment.

### MODE FOR THE INVENTION

Example embodiments will be described below in greater detail with reference to the accompanying drawings. The example embodiments described below may be modified and implemented in various different forms. In order to more clearly describe the features of the example embodiments, a detailed description of known matters to those skilled in the art will be omitted.

Meanwhile, in the present disclosure, a case in which any one feature is connected with the other feature includes a case in which the features are directly connected with each other and a case in which the parts are electrically connected with each other with other features interposed therebetween. Further, when a certain feature is stated as “comprising” a certain feature, unless otherwise stated, this means that the certain feature may include another feature, rather than foreclosing the same.

The term “image forming job” as used herein may mean various jobs related to the image (e.g., printing, scanning or faxing), such as forming an image or creating/storing/transmitting an image file. In addition, “job” may mean not only an image forming operation but also a series of processes necessary for performing an image forming operation.

An image forming apparatus generally operates to print out print data generated at a terminal such as a computer onto a printing paper. An example of an image forming apparatus includes a copier, a printer, a facsimile and a multifunction printer (MFP) that provides combined functionality of at least two of the single apparatuses. The image forming apparatus may refer to all apparatuses capable of performing an image forming operation, such as a printer, a scanner, a fax machine, an MFP, a display apparatus, or the like.

In addition, “hard copy” may refer to an operation of outputting an image on a printing medium such as paper, and the like, and “soft copy” may refer to an operation of outputting an image in a display apparatus, such as a TV, monitor, and the like.

In addition, “content” may refer to all types of data that are subject to an image forming operation, such as a photo, image, document file, or the like.

In addition, “print data” may refer to data that is converted into a format printable in a printer. Meanwhile, if a printer supports direct printing, the file itself may be print data.

In addition, “user” may refer to a person who performs an operation related to an image forming operation using an image forming apparatus or a device connected to the image forming apparatus via wire or wirelessly. In addition, “manager” may refer to a person who has the authority to access all functions and the system of the image forming apparatus. The “manager” and the “user” may be the same person.

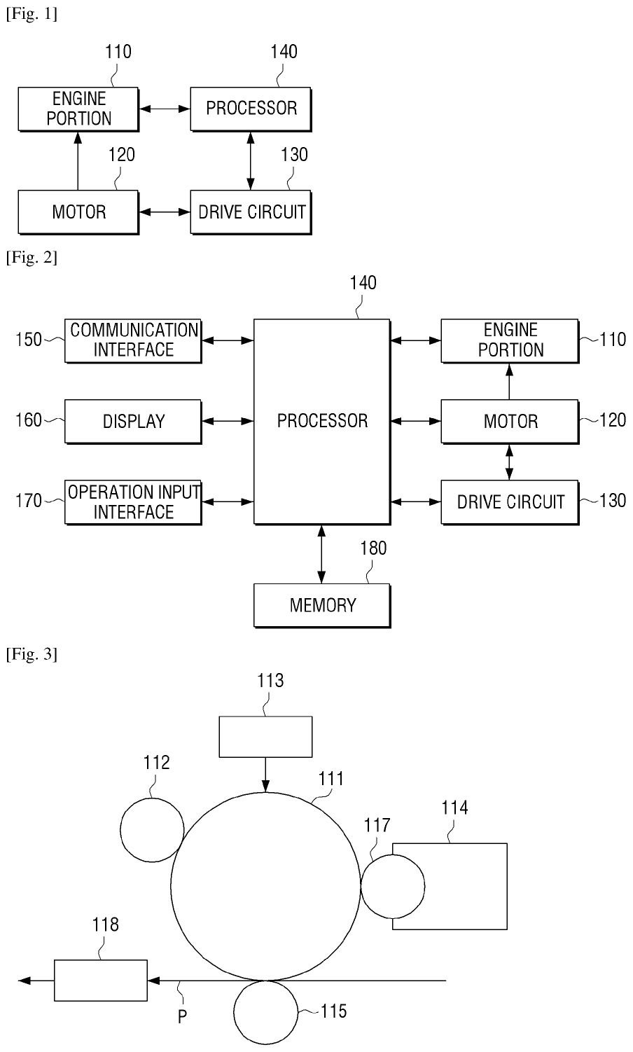

FIG. 1 is a block diagram illustrating a brief configuration of an image forming apparatus, according to an example embodiment.

Referring to FIG. 1, an image forming apparatus 100 may include an engine portion 110, a motor 120, a drive circuit 130, and a processor 140.

Here, the image forming apparatus 100 is an apparatus which performs generation, printing, reception, and transmission of image data, and may be a printer, a copy machine, a facsimile, and a multifunction peripheral (MFP) in which functions of at least two of the above-described devices are combined. In this embodiment, it is described that the present disclosure is applied to the image forming apparatus to form an image, but the present disclosure may also be applied to an image reading apparatus, such as a scanner.

The engine portion 110 performs an image forming job. Specifically, the engine portion 110 may perform the image forming job under the control of the processor 140 and the start of the motor 120. In this embodiment, it is described that the engine portion 110 performs only the image forming job. However, if the image forming apparatus 100 is a scanner that can perform scan operations or a multifunction peripheral apparatus, the engine portion 110 may be configured to perform an image reading operations. The detailed configuration of the engine portion 110 will be described later with reference to FIG. 3.

The motor 120 starts the engine portion 110. For example, the motor 120 may be included within the image forming apparatus 100, and may include a DC motor, a step motor, and a brushless DC (BLDC) motor. The motor 120 may perform various functions of the image forming apparatus, such as driving an organic photo conductor (OPC), driving a fuser, and feeding paper. Although FIG. 1 illustrates only one motor, in example embodiments, a plurality of motors may be included in the image forming apparatus 100. Hereinafter, for convenience of explanation, an example in which one motor is used will be described first and then, an operation when a plurality of motors are used will be described.

The drive circuit 130 may generate a drive signal with respect to the motor 120 according to a drive command. In addition, the drive circuit 130 may provide a predetermined power to the motor 120. For example, when a motor is a step motor, the drive circuit 130 may receive a drive command (for example, current magnitude information and speed information), provide a constant current to the step motor in response to the received current magnitude information, and provide an impulse drive signal corresponding to the speed information to the step motor. In addition, when a motor is a BLDC motor, the drive circuit 130 may receive speed information, provide a predetermined constant voltage to the BLDC motor, and provide a drive signal corresponding to the received speed information to the BLDC motor. The detailed configuration and operation of the drive circuit 130 will be described later with reference to FIG. 5.

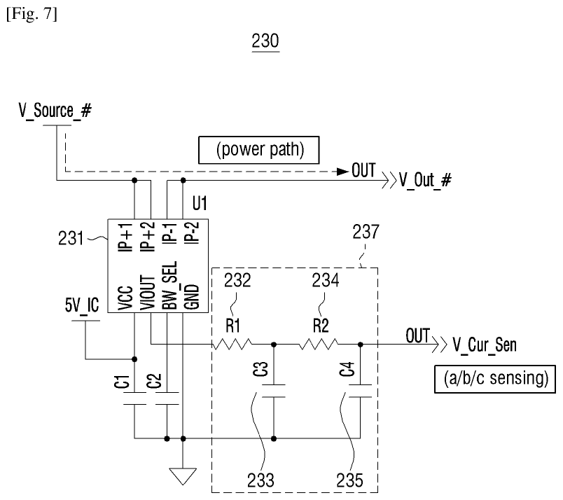

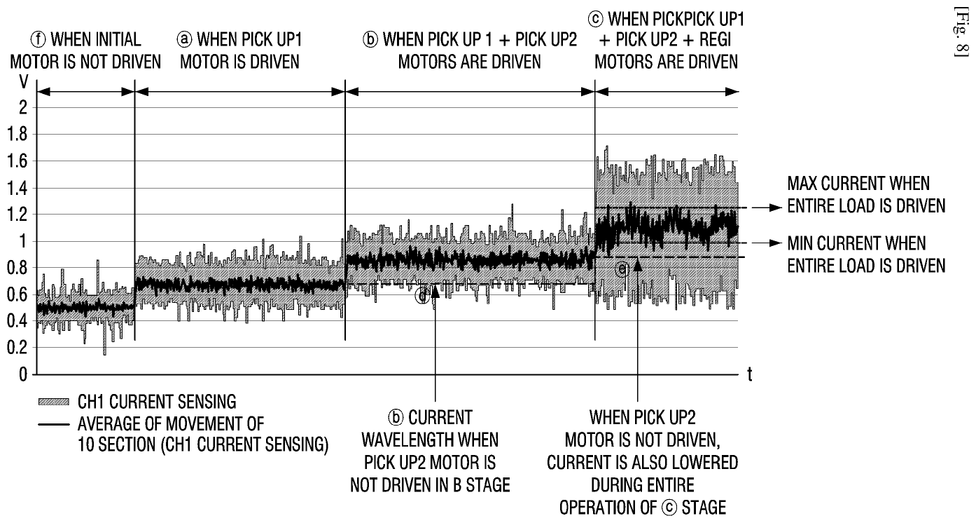

In addition, the drive circuit 130 may include a sensor which detects an amplitude of current provided to the motor. In this regard, the sensor may be disposed on a power line between an output terminal of a power unit and a power input terminal of a motor, and may detect an amplitude of current based on an electric field on the power line. The detailed operation of the sensor will be described later with reference to FIGS. 6 and 7.

The processor 140 controls the respective configurations in the image forming apparatus 100. For example, if print data is received from a print control terminal device, the processor 140 controls the operation of the engine portion 110 to print the received print data, and transmits a drive command for the motor that starts the engine portion 110 to the drive circuit 130. For example, the processor 140 may transmit a drive command for the motor such as a rotation start/stop, acceleration/moderation, velocity reference value command and the like to the drive circuit 130.

In addition, when a motor 120 to be controlled is a step motor, the processor 140 may provide, to the drive circuit 130, a current reference value (Vref) (hereinafter referred to as ‘constant current control value’) as a drive command so that a predetermined constant current is provided to the step motor. In this regard, the constant current control value may be in the form of a pulse-width modulation (PWM) signal.

In addition, when a motor 120 to be controlled includes a brake member, the processor 140 may provide an operation command of the brake member as a drive command to the drive circuit 130.

In addition, the processor 140 receives information relating to an amplitude of current detected by the drive circuit 130. For example, the processor 140 may determine a load size of a motor based on an amplitude of voltage transferred through an analog to digital (ADC) port (or terminal). In this regard, an amplitude of voltage transferred through the ADC port may correspond to an amplitude of current detected by a sensor.

In addition, the processor 140 determines whether or not a motor has an abnormality based on the received current magnitude information. For example, when a drive command provided to the motor is normally processed, the processor 140 may determine the abnormality of the motor based on information relating to possible current ranges (that is, information relating to a lower limit of current and information relating to an upper limit of current) and the detected current magnitude.

In this regard, the reason for having different current ranges for each drive command is that the load size applied to the motor may vary depending on the drive command. For example, since the motor does not feed paper during the warm-up process just before printing, the load on the motor is small. However, in the actual printing process, the load on the motor is increased.

In this respect, the processor 140 may determine whether the motor has an abnormality based on only information relating to the detected current corresponding to one drive command, but may alternatively provide different drive commands to the motor 120 sequentially and determine whether the motor has an abnormality based on the detected current information according to each drive command. For example, the processor may primarily provide a first drive command to drive at a first speed to the motor 120, and then secondarily provide a second drive command to drive at a second speed higher than the first speed to the motor 120.

In addition, the processor 140 may determine the abnormality of the motor in consideration of first current information and second current information after each drive command comprehensively.

In addition, a size of load on the motor may vary depending on the type of printing paper and thus, the current range information described above may have different values simply according to a drive command and may have different values according to a drive command and a type of printing paper.

In addition, in example embodiments, the current range information described above may be one range to determine normal or error in any print paper or any drive command.

Meanwhile, the processor 140 may not use the entire current magnitude that is detected after a drive command is received, and may determine the abnormality by using only the current amplitude detected a predetermined time after the drive command is received. For example, in the case of a BLDC motor, a large amount of current is supplied at the time of initial operation. In order not to determine whether the current suddenly increases at this early stage or not is related to abnormality, when the current range information is widened, it may be difficult to detect abnormality as described above. Thus, the current range information may be set to determine an error in an interval excluding the initial operation, and an amplitude of current immediately after the drive command may not be used to determine an error.

In addition, when determining that the motor has an abnormality, the processor 140 may determine a reason for the abnormality based on the detected current magnitude. For example, the processor 140 may determine an abnormality reason corresponding a currently-detected current magnitude by using a lookup table corresponding to an abnormality cause for each current magnitude.

For example, if the motor is deteriorated, the motor will operate normally but the power consumed may be somewhat higher than the normal state. Accordingly, when an amplitude of a current detected after a drive command fluctuates near the upper current limit, the processor 140 may determine that the motor is deteriorated.

In addition, when the motor is not operated at all, the current may be very low or may not be supplied. Accordingly, when an amplitude of a current detected after a drive command fluctuates below the lower current limit, the processor 140 may determine that the failure of the motor is the cause of the abnormality.

If the motor is not faulty, but there is a fault in another member connected to the motor (for example, jamming, gear failure of the coupling part), a current much higher than the normal range may be supplied. Accordingly, when the amplitude of the current sensed after the drive command exceeds the current upper limit value, the processor 140 may determine that jamming or an abnormality of the coupling part connected to the motor is the cause of the abnormality. In the above example embodiment, the cause of the abnormality is determined based on the amplitude of the current corresponding to one drive command. In example embodiments, an amplitude of current before a drive command and an amplitude of current of a drive command may be considered together, and multiple drive commands with respect to one motor may be applied and a cause of the abnormality may be determined based on an amplitude of current according to each drive command.

In addition, the processor 140 may determine a state of a motor by comparing prestored current information and currently-detected current information. For example, the processor 140 may compare current information in the past that is pre-stored in the memory 180 (see FIG. 2) with current information in the same drive state, and may determine that the motor is deteriorated when the difference is more than a predetermined value.

In addition, when it is detected that the motor has an abnormality, or the motor is found to be defective, the processor 140 may stop driving of the motor. For example, the processor 140 may stop the work in progress if it detects an abnormality of the motor and it is determined that the identified fault is serious.

In addition, when a motor fault is detected, the processor 140 may control the display 160 (see FIG. 2) to display information relating to the motor fault. In this regard, the displayed information may include information relating to a motor in which the fault is detected, manual information for correcting the corresponding fault, and the like. For example, when the detected error is jamming, the processor may control the display 160 to display that a jamming has occurred and how to remove a printing paper in the engine portion.

If it is difficult for the user to fix the corresponding fault (or error) by himself/herself, the processor 140 may automatically notify a management server corresponding to a service center of the corresponding error.

Meanwhile, checking the abnormality of the motor as described above may be carried out in real time during a normal printing process. In addition, the processor 140 may provide a drive signal to a motor at a predetermined time point, and may test whether the motor has an abnormality based on an amplitude of a current according to the drive signal. In this regard, the predetermined time point may be a point of initial operation of an image forming apparatus, may be a warm-up point time before a printing operation is actually carried out, or may be a time point at which the number of printed papers is more than a predetermined number.

For example, when a print command is received in an image forming apparatus, the processor 140 may control the engine portion 110 to perform a warm-up for performing a printing operation, and may perform the above-described operation to detect an abnormality in the motor during the warm-up process.

In the above example embodiment, the abnormality with respect to one motor is detected. However, an image forming apparatus 100 may include a plurality of motors as well. In this case, the processor 140 may apply a drive command to a plurality of motors sequentially and sequentially determine the abnormality of each of the motors, or may simultaneously apply a drive commands by group and determine the abnormality of the corresponding group based on an amplitude of current supplied to each of the groups.

If it is determined that the motor group has an abnormality, the processor 140 may sequentially provide a drive command to each of the motors in the group and identify a motor that is faulty. The detailed description of detecting the abnormality of a plurality of motors will be described later with reference to FIGS. 5 and 6.

In the above example embodiment, the processor 140 determines the abnormality of the motor 120. In example embodiments, it may also be configured such that a drive circuit 130 may determine the abnormality of the motor, and that only when determining that the motor is abnormally operated, the drive circuit 130 transfers information relating to the abnormality to the processor 140.

In the above example embodiment, the processor 140 determines only the abnormality in the motor 120. In example embodiments, it is also possible to receive, in the image forming apparatus 100, current information for each configuration operating through the power supply, and to determine whether the configuration other than the motor is abnormal. This will be described below with reference to FIG. 6.

In the above example embodiment, the drive circuit 130 includes a sensor which detects an amplitude of current. In example embodiments, the corresponding sensor may be an additional sensor having a separate drive circuit 130.

On the other hand, FIG. 1 illustrates that the motor 120 and the drive circuit 130 are separately configured. During implementation, however, the motor 120 may be implemented as a configuration in the drive circuit 130.

Meanwhile, although the above illustrates and explains the simple constitution of the image forming apparatus, various new units may be additionally included in actual implementation. It will be explained below by referring to FIG. 2.

FIG. 2 is a block diagram illustrating an example configuration of the image forming apparatus according to an example embodiment.

Referring to FIG. 2, the image forming apparatus 100 according to an example embodiment of the present disclosure may include an engine portion 110, a motor 120, a drive circuit 130, a processor 140, a communication interface 150, a display 160, an operation input interface 170, and a memory 180.

The engine portion 110, the motor 110, and the processor 140 perform the same function as those of FIG. 1, and thus, the description thereof will be omitted.

The communication interface 150 is connected to a print control terminal device (not illustrated), and receives print data from the print control terminal device. For example, the communication interface 110 is formed to connect the image forming apparatus 100 to an external device, and may be connected to the terminal device through not only a local area network (LAN) or the Internet but also a universal serial bus (USB) port or a wireless communication (e.g., Wi-Fi 802.11a/b/g/n, near field communication (NFC), or Bluetooth) port. In this regard, a print control terminal may be a general PC or a laptop PC, and may be a mobile device such as a smart phone.

The communication interface 150 receives print data from the print control terminal device. Further, if the image forming apparatus 100 has a scanner function, the communication interface 110 may transmit generated scan data to the print control terminal device or an external server (not illustrated).

In addition, when the abnormality of the motor is determined in the image forming apparatus, the communication interface unit 150 may provide information relating to the abnormality to the management server corresponding to the service sensor.

The display 160 may display various information provided from the image forming apparatus 100. For example, the display 160 may display an operation state of the image forming apparatus 100, or may display a user interface window for selecting functions and options that the user can select. The display 160 may be a monitor, such as liquid crystal display (LCD), CRT, and the like, and may be implemented by a touch screen that may simultaneously perform the function of the operation input unit 170 to be described later.

Further, the display 160 displays the operation state of the image forming apparatus 100. When the abnormality in the motor is determined, the display 160 may display information corresponding to a type of the determined defect. The information displayed at this time may include information relating to the defect itself, manual information for solving the corresponding defect, and information such as contact information (or contact method) of the service sensor.

Further, the operation input interface 170 may include a plurality of function keys with which the user may set or select various functions supported by the image forming apparatus 100. The operation input interface 170 may be implemented as an apparatus such as a mouse, a keyboard, and the like, and may also be implemented as a touch screen capable of simultaneously performing the functions of the display 160 described above. Through the above process, the user can input various drive commands with respect to the image forming apparatus 100.

In addition, when the image forming apparatus 100 has a plurality of paper loading containers, the operation input interface 170 may select a paper loading container to be used for the print job. Alternatively, the operation input interface 170 may receive various information associated with printing papers to which a print job is to be performed. In this regard, the various information associated with the printing paper may be a paper size, coating information, thickness information, and the like.

The memory 180 may store print data. For example, the memory 180 may store print data that is received through the communication interface 150 described above. The memory 180 may be implemented to be an external storage medium, a removable disk that includes a Universal Serial Bus (USB) memory, and/or a web server through a network as well as a storage medium within the image forming apparatus 100.

In addition, the memory 180 may store a lookup table usable to control the motor 120. Here, the lookup table may be an acceleration table having pulse cycle information for drive speeds of the step motor, and may be a speed or acceleration table corresponding to a plurality of load voltages (Vload), a lookup table for torque values that correspond to a plurality of load voltages Vload, or a lookup table for constant current control voltages, for example Vref values or control voltage values, that correspond to the plurality of load voltages Vload.

In addition, the memory 180 may store the current lower limit value information and the current upper limit value information in the form of a lookup table in the normal operation for each of the motors to determine the abnormality of the motor. The information relating to the lower limit value and the upper limit value may be individually stored per drive command.

In addition, the memory may store information regarding an amplitude of a current outputted from a sensor.

In the current embodiment, it is described that the memory 180 stores a lookup table. However, in example embodiments, the lookup table may be stored in the drive circuit 130 or the processor 140, which will be described later.

As described above, the image forming apparatus 100 according to the example embodiment may determine whether the motor is abnormal even if a sensor capable of detecting an abnormality in the drive portion is not used. Accordingly, a structure of an image forming apparatus can be further simplified, and a circuit configuration can be made easier and with lower cost.

In addition, the image forming apparatus 100 can continuously monitor the change in the current of the motor and can predict the possibility of an abnormality of the apparatus due to the life of the component caused by the increase in the load of the instrument drive gear friction portion or the increase in the coupling load on the assembly.

In addition, the image forming apparatus 100 may accurately identify in which configuration an error has occurred even if the motor failure occurs, making it easy to fix the failure.

FIG. 3 is a diagram of an engine portion, according to an example embodiment.

Referring to FIG. 3, the engine portion 110 may include a photosensitive drum 111, a charger 112, an exposure equipment 113, a developer 114, a transfer equipment 115, and a presser 118.

The engine portion 110 may further include a feeding means (not illustrated) which supplies a printing medium (P). An electrostatic latent image is formed in the photosensitive drum 111. The photosensitive drum 111 may be referred to as a photosensitive drum, a photosensitive belt, and the like, according to forms.

Hereinafter, for the convenience of explanation, the feature of the engine portion 110 corresponding to one color will be described as an example, but at the time of implementation, the engine portion 110 may include a plurality of photosensitive drums 111 corresponding to a plurality of colors, a plurality of chargers 112, a plurality of exposure devices 113, a plurality of developing devices 114, and an intermediate transfer belt.

The charger 112 charges the surface of the photosensitive drum 111 to a uniform potential. The charger 112 may be implemented as a corona charger, a charging roller, a charging brush, and the like.

The exposure device 113 may change the surface potential of the photosensitive drum 111 based on information on an image to be printed to form an electrostatic latent image on the surface of the photosensitive drum 111. As an example, the exposure device 113 may form an electrostatic latent image by irradiating the photosensitive drum 111 with light modulated in accordance with the information on the image to be printed. An exposure device 113 of this type may be referred to as a light scanning device or the like, and an LED may be used as a light source.

The developing device accommodates the developer therein, and supplies the developer to the electrostatic latent image to develop the electrostatic latent image into a visible image. The developing device 114 may include a developing roller 117 for supplying the developer to the electrostatic latent image. For example, the developer may be supplied from the developing roller 117 to the electrostatic latent image which is formed on the photosensitive drum 111 by the developing electric field formed between the developing roller 117 and the photosensitive drum 111.

The visible image which is formed on the photosensitive drum 111 is irradiated to a recording medium (P) by the transfer device 115 or an intermediate transfer belt (not illustrated). The transfer device 115 may transfer the visible image to a recording medium, for example, by the electrostatic transfer method. The visible image is attached to the recording medium (P) by electrostatic attraction.

The fixing device 118 fixes a visible image on the recording medium P by applying heat and/or pressure to a visible image on the recording medium P. The printing operation is completed by this series of processes.

The developer described above are used every time an image forming operation is made and exhausted when used for or more than a predetermined period of time. In such a case, it is necessary to replace the developer storage unit, for example, the developing device 114 described above. Components or configurative elements that may be replaced in the process of using an image forming apparatus are called consumable units or replaceable units. In addition, for proper management of the corresponding consumable unit, memory or CRUM chip may be attached to the consumable unit.

Meanwhile, the motor 120 may perform an operation of rotating each configuration of the engine portion 110 described above. In example embodiments, one motor 120 may simultaneously rotate a plurality of configurations of the engine portion 110 described above. Alternatively, a plurality of motors in combination may rotate the plurality of configurations described above.

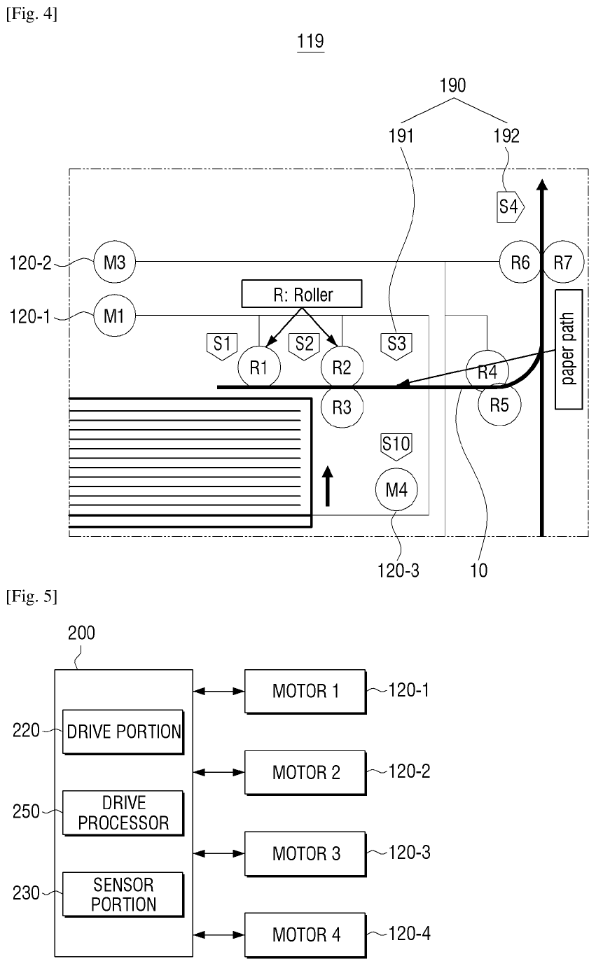

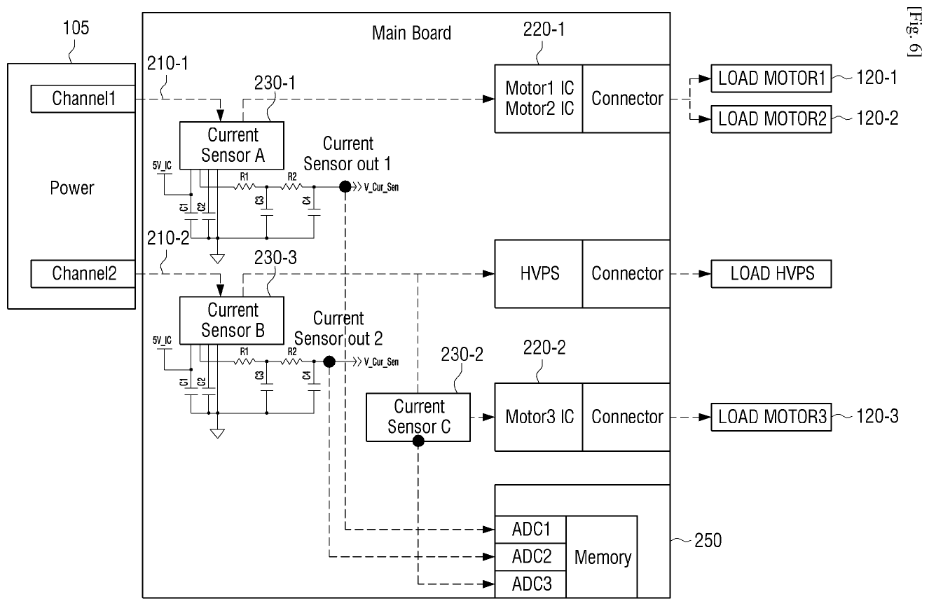

In the illustrated example, it is illustrated and described only a configuration directly related to image forming. However, the engine portion 110 may further include a paper transferring portion 119 which moves papers loaded in the loading container to the transfer portion and pressing portion described above. The configuration of such a paper transferring portion will be described later with reference to FIG. 4.

FIG. 4 illustrates an example configuration of a paper transferring portion.

Referring to FIG. 4, the paper transferring portion 119 moves a printing papers loaded in a loading container to a predetermined paper transferring path. To this end, the paper transferring portion 119 may include a plurality of motors 120-1, 120-2 and 120-3 and structures R1, R2, R4 and R6 that are movable by the plurality of motors 120-1, 120-2 and 120-3.

The plurality of motors 120-1, 120-2 and 120-3 provides power for activating a structure. For example, a first motor 120-1 drives a plurality of rollers R1 and R2 to put a manuscript loaded in a loading container in a paper transferring path.

In addition, a second motor 120-2 drives a plurality of rollers R4 and $R6 to move printing papers discharged from a loading container to the transferring device and the fixing device.

A third motor 120-3 raises the printing paper in the loading container to the upper end and activates an instrument for bringing the printing paper into contact with the roller R1.

Through the configuration described above, when a print command is received, the processor 140 may provide a drive command to the plurality of motors 120-1 and 120-2 to operate a drive speed corresponding to a printing speed.

Based on the drive command, the plurality of motors 120-1 and 120-2 drives the structures R1, R2, R4 and R6 and accordingly, printing papers loaded in the loading container are moved to the transferring device in the engine portion 110.

Meanwhile, in related art, to identify whether the paper transfer in this process is normally performed, paper sensors 191 and 192 disposed on the paper transferring path 10 are used. That is, when it is identified that papers are sequentially sensed according to signals S3, S4 output from the paper sensors 191 and 192, the processor 140 determined that the plurality of motors 120-1, 120-2 and 120-3 are operated normally.

However, such a paper detection sensor 190 is difficult to install because it needs to be disposed on the movement path of the paper. In addition, in order to check whether the motor is operating normally, it is not possible to confirm the initial product error because the paper feeding test is actually performed to check whether the motor is abnormal.

In this respect, in the example embodiment, it is identified whether the motor is normally operated, by using a current supplied to the motor. For example, the first motor 120-1 performs activation after a first drive command and thus, the structures R1 and R2 pick up a printing paper.

As the structures pick up a printing paper, the load on the first motor 120-1 is increased, and when the paper feeding is ended, the load is decreased.

Such a load variation can be identified by the processor 140 through a current sensor. That is, even if related-art paper sensor is not used, whether the motor is operated normally can be identified by only a change in current magnitude flowing in the motor.

If there is no paper in the loading container, a current flowing through the first motor 120-1 may not vary significantly even if a drive command is received. Accordingly, the processor may identify that a paper loaded in the loading container is not transferred to the paper transferring path. In addition, based on the above, the processor 140 may display an error state in which there is no printing paper, on a display.

If a jamming occurs while a paper is transferred from the loading container to the paper transferring line, a current is increased by more than a predetermined value after the first motor 120-1 provides a drive command, and an amplitude of the current may be further increased by the jamming. In this regard, when a current of the second motor 120-2 is maintained low, for example in a state in which a printing paper does not pass through an instrument driven by the second motor, the processor 140 may identify that a paper jamming has occurred between the loading container and the paper transferring line.

In the above example embodiment, only the operation of the paper transferring portion disposed on the loading container is described. However, the above-described operation may be applied on the transferring path of the printing paper in the engine portion.

FIG. 5 illustrates a configuration of a drive circuit of FIG. 1.

Referring to FIG. 5, the motor control apparatus 200 controls a plurality of step motors 120-1, 120-2, 120-3, and 120-4. In this regard, the motor control apparatus 200 is a configuration corresponding to the drive circuit of FIG. 1. Although FIG. 1 illustrates that determination of whether a motor is abnormal or not is made in the processor, the motor control apparatus of FIG. 5 is an apparatus which performs some operations of the processor of FIG. 1, for example operations of determining an abnormality. The motor control apparatus 200, which will be described below, may be included in an image forming apparatus, and may be configured as a separate device other than the image forming apparatus.

The plurality of motors 120-1, 120-2, 120-3 and 120-4 may be the same step motors, and the step motor, the BLDC motor, and the DC motor may be used interchangeably. That is, the motor control apparatus 200 may be configured to generate a drive signal with respect to a step motor and controls the BLDC motor and the DC motor.

The motor control apparatus 200 may include a drive portion 220, a sensor portion 230, and a drive processor 250.

The drive portion 220 provides the plurality of motors 120-1, 120-2, 120-3 and 120-4 with power corresponding to each motor. Hereinbelow, for convenience of explanation, it will be assumed that the first motor 120-1 and the second motor 120-2 are step motors, and that the third motor 120-3 and the fourth motor 120-4 are BLDC motors.

First, the drive portion 220 may provide a predetermined constant current to the first motor 120-1 based on a drive signal with respect to the first motor 120-1 transferred from the drive processor 250 and a current reference value (Vref). In the same manner, the drive portion 220 may provide the second motor 120-2 with a predetermined constant current corresponding to the second motor 120-2. In addition, the drive portion 220 may provide a constant voltage of a predetermined magnitude to the third motor 120-3 and the fourth motor 120-4.

Meanwhile, in the illustrated example, the motor drive apparatus 200 includes one drive portion 220. However, in example embodiments, the number of drive portions may be as many as the number corresponding to the number of motors. Alternatively, a different drive portion 220 may be provided for each motor type.

The sensor portion 230 measures an amplitude of current of power supplied to a power input terminal of each motor. For example, the sensor portion 230 may detect an amplitude of current of power supplied to each motor by using a sensor detecting an amplitude of current based on an electric field.

In the above example embodiment, a sensor using a magnetic field is used and thus, a current provided to each motor can be detected using the same sensor regardless of a type of motor, such as BLDC motor, step motor, or the like.

In addition, such a sensor may be disposed in the output terminal of the motor, and may be disposed in the input terminal. Accordingly, one sensor may commonly sense a current supplied to a plurality of motors. An example thereof will be described below with reference to FIG. 6.

Meanwhile, the sensor portion 230 may include a smoothing circuit for smoothing an output value of a sensor. The output value of the smoothing circuit may be a sensing voltage value (Vsens), and the corresponding value may be provided to an analog-to-digital converter (ADC) terminal of a drive processor 250 or a processor 140.

The drive processor 250 receives the drive command from the controller 140, and may control the drive portion 220 based on the received drive command to control a drive state of the motor. For example, the drive processor 250 may receive a drive command for the motor from the processor 140. In this regard, the drive command may include a start/stop of rotation of the step motor, an acceleration/deceleration, a velocity reference value, and whether the brake is operated, or the like.

The above-described drive command may be received from the processor 140 through an SPI (Serial Peripheral Interface), which is an interface that enables two devices to exchange data through serial communication and a serial communication interface such as I2C that is a bidirectional serial bus.

Then, the drive processor 250 generates a drive signal for the motor 120 according to the received drive command. Specifically, when the step motor is controlled, the drive processor 250 may generate the drive signal by using pulse cycle information of a speed change period that corresponds to the drive command in the acceleration table. Here, the acceleration table is a table having the pulse cycle information by drive speeds of the step motor 150. The acceleration table may be stored within the drive processor 250, may be stored in the above-described memory 180, or may be read by the drive processor 250 if needed.

In addition, when a motor 120 to be controlled is a step motor, the drive processor 250 may provide, to the drive portion 220, a current reference value (Vref) (hereinafter referred to as ‘constant current control value’) as a drive command so that a predetermined constant current is provided to the step motor. In this regard, the constant current control value may be in the form of a pulse-width modulation (PWM) signal.

In addition, when a motor 120, for example motor 120-2, to be controlled includes a brake member, the drive processor 250 may provide an operation command of the brake member as a drive command to the drive portion 220.

In addition, the drive processor 250 receives information relating to an amplitude of current detected by the sensor portion 230. For example, the drive processor 250 may determine a load state of each motor based on an amplitude of voltage transferred through an ADC port (or terminal). In this regard, an amplitude of voltage transferred through the ADC port corresponds to an amplitude of current detected by a sensor.

In addition, the drive processor 250 determines whether or not a motor has an abnormality based on the received current magnitude information. For example, when a drive command provided to the motor is normally processed, the drive processor 250 may determine the abnormality of the motor based on information relating to possible current ranges (that is, information relating to a lower limit of current and information relating to an upper limit of current) and the detected current magnitude.

Meanwhile, the drive processor 250 may not use the entire current magnitude that is detected after a drive command is received, and may determine the abnormality by using only the current amplitude detected a predetermined time after the drive command is received (hereinafter, an operation of using only an amplitude of after a predetermined time is referred to as ‘masking operation’). Such a masking operation may not be applied to all motors, but may be applied to only current magnitudes of some motors.

In addition, when determining that the motor has an abnormality, the drive processor 250 may determine a reason for the abnormality based on the detected current magnitude. For example, the drive processor 250 may determine an abnormality reason corresponding a currently-detected current magnitude by using a lookup table corresponding to an abnormality cause for each current magnitude.

In addition, when it is detected that the motor has an abnormality, or the motor is found to be defective, the drive processor 250 may stop driving of the motor. For example, the drive processor 250 may stop driving of all motors if it detects an abnormality of the motor and it is determined that the identified fault is serious.

Meanwhile, checking the abnormality of the motor as described above may be carried out at all times. In addition, when a test command is received from the processor 140, the motor control apparatus 200 may provide a drive command for each motor or for each motor group and identify whether the motor is abnormal based on an amplitude of current according to the drive command.

As described above, the motor control apparatus 200 according to the example embodiment may determine whether the motor is abnormal even if a sensor capable of detecting an abnormality in the drive portion is not used. In addition, the motor drive apparatus 200 can continuously monitor the change in the current of the motor and can predict the possibility of an abnormality of the apparatus due to the life of the component caused by the increase in the load of the instrument drive gear friction portion or the increase in the coupling load on the assembly.

In the illustrated example, it is illustrated that the motor control apparatus 200 is not provided with the motor 120. During implementation, however, the motor control apparatus 200 may be provided to include the motor 120.

In addition, FIG. 5 illustrates and describes that the drive portion 220 and the drive processor 250 are separate configurations. However, in example embodiments, the drive portion 220 and the drive processor 250 may be implemented as one configuration.

FIG. 6 is a circuit diagram of the drive circuit of FIG. 1.

Referring to FIG. 6, the motor control apparatus 200 may include a drive power portion 210, a plurality of drive portions 220-1 and 220-2, a plurality of sensors 230-1, 230-2 and 230-3, and a drive processor 250.

The drive power portion 210 provides power provided from the power portion 105 to each configuration in the motor control apparatus 200. When the motor control apparatus 200 utilizes a plurality of powers, the drive power portion 210 may receive different powers from the power portion 105 via a plurality of channels.

The first drive portion 220-1 may receive power of a first channel and generate a constant current corresponding to each of a plurality of motors 120-1 and 120-2. In addition, the first drive portion 220-1 may provide the generated constant current to each of the motors 120-1 and 120-2. The constant current generated at this time corresponds to a constant current control value (Vref) which is provided from the drive processor 250.

In addition, the first drive portion 220-1 may provide an impulse signal for driving each of the first motor 120-1 and the second motor 120-2 based on a drive command provided from the drive processor 250.

The second drive portion 220-2 may receive power of a second channel and provide a constant voltage to a third motor 120-3. In addition, the second drive portion 220-2 may perform speed control with respect to the third motor 120-3 based on a drive command provided from the drive processor 250.

In addition, the second drive portion 220-2 may control the operation of a brake member within the third motor 120-3 based on a drive command provided form the drive processor 250.

The sensor portion 230 detects an amplitude of a power supplied to each motor. Specifically, the sensor portion 230 may include a first sensor 230-1, a second sensor 230-2, and a third sensor 230-3. Each sensor may be different only in disposition position, but they may be the same type of sensors, that is, a current detecting sensor which detects an amplitude of current based on an electric field flowing through a power line.

The first sensor 230-1 may be disposed between a first input terminal 210-1 receiving a first output of the power portion 105 and the first drive portion 220-1 and detect an amplitude of current of a power commonly provided to the first motor 120-1 and the second motor 120-2.

The second sensor 230-2 may be disposed between a second input terminal 210-2 receiving a second output of the power portion 105 and the second drive portion 220-2 and detect an amplitude of current of a power commonly provided to the third motor 120-3.

The third sensor 230-3 may be disposed between a second input terminal 210-2 receiving a second output of the power portion 105 and a plurality of drive portions 220-2 (HVPS) and detect an amplitude of current of a power provided to the second drive portion and the HVPS.

The amplitude of current of power detected in the first sensor 230-1, the second sensor 230-2 and the third sensor 230-3 may be provided to an ADC port of the drive processor 250.

The detailed configuration of the first, second and third sensors will be described later with reference to FIG. 7.

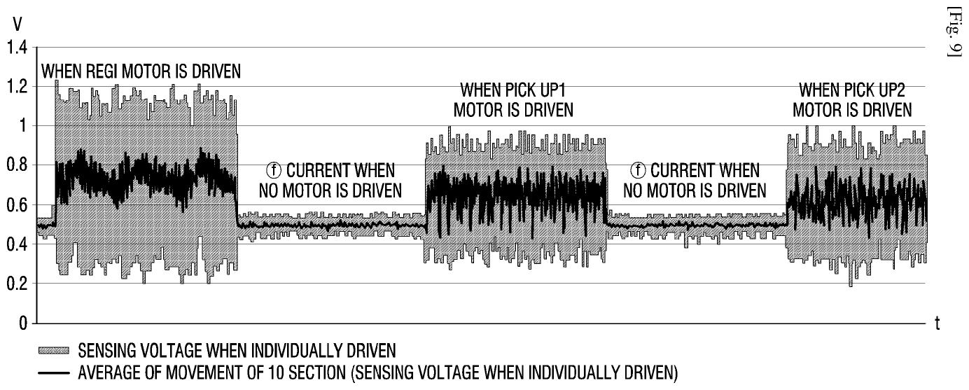

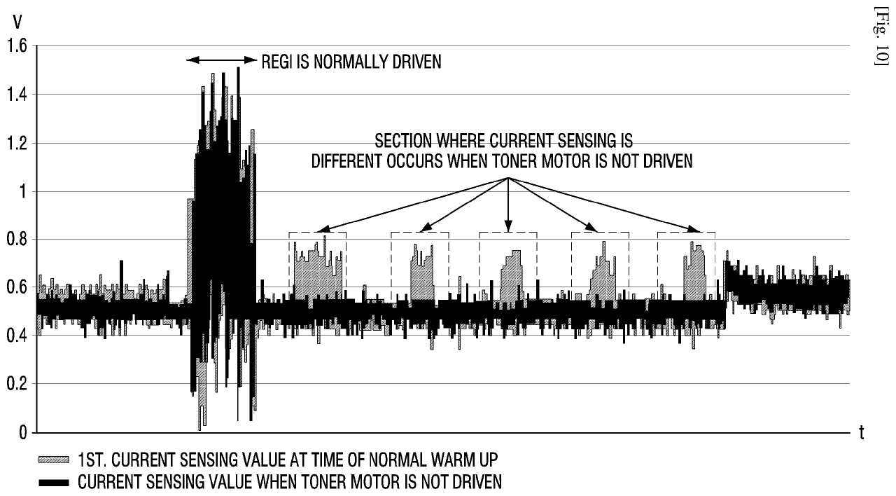

The drive processor 250 may receive information relating to a current detected from the plurality of sensors 230-1, 230-2 and 230-3, and determine the abnormality of the plurality of motors 120-1, 120-2 and 120-3 based on the received current information. The detailed process of determining the abnormality based on the current amplitude detected this way will be described later with reference to FIGS. 8 to 9.

It is determined in the above example embodiment that the drive processor 250 detects only the abnormality of a plurality of motors. However, in example embodiments, the abnormality of the drive portion (HVPS), not the motor, may be determined based on an amplitude of current detected in the third sensor 230-3 and the second sensor 230-2. In other words, it can be determined that an abnormality of the HVPS occurs when the change of the current amplitude in the third sensor exceeds a predetermined range even though the current amplitude is not largely changed in the second sensor.

FIG. 7 illustrates a sensor unit.

Referring to FIG. 7, the sensor unit 230 is disposed on a power path, and includes a sensor 231 and a smoothing circuit 237.

The sensor 231 detects a magnetic field generated according to a current flow within the power path, and outputs information relating to an amplitude of current corresponding to the detected magnetic field as a voltage magnitude.

Meanwhile, a step motor is operated as an impulse signal and thus, when a voltage value output from the sensor 231 is directly used, it is impossible to detect an amplitude of current accurately.

In this respect, the smoothing circuit 237 may smooth an output value of the sensor 231 and provide the smoothed voltage value to an ADC port of the drive processor 250.

The smoothing circuit 237 is a resistor-capacitor (RC) smoothing circuit including a plurality of resistors 232 and 234 and a plurality of capacitors 233 and 235. In the illustrated example, a smoothing circuit is configured using two serially-connected RC circuits. However, in example embodiments, it is possible to use only one RC circuit, or to configure a smoothing circuit through a circuit configuration other than the RC circuit.

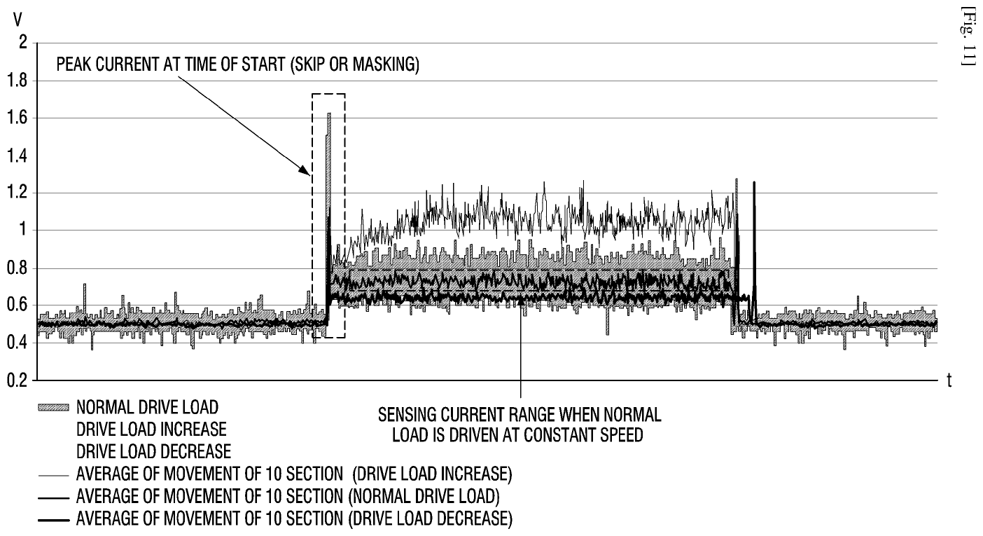

FIGS. 8, 9, 10, and 11 are diagrams illustrating a method for determining an abnormality based on a drive current detected by a sensor.

For example, FIG. 8 illustrates a method of determining the abnormality of a plurality of motors in a case in which the plurality of motors are driven concurrently.

Meanwhile, a plurality of motors may be driven concurrently, or a plurality of motors may be cumulatively driven in stages.

First, a method of determining the abnormality of a plurality of motors in a case in which the plurality of motors are cumulatively driven will be described below.

Referring to FIGS. 8 and 9, it is possible to sequentially drive a plurality of motors during the initial set warm-up operation or in the set check stage before going to the preparation stage.

The section \textcircled{a} is a section for driving a first motor only, the section \textcircled{b} is a section for driving the first motor and a second motor concurrently, and the section \textcircled{c} is a section in which a third motor is added to first motor and the second motor and cumulatively driven sequentially. Referring to a current value detected in each section, it can be identified that the motor is cumulatively driven in stages and a load current required for the drive is accordingly increased.

In this way, since the motor or the load to be driven is added for each specific section, the load current required for driving needs to be larger than before, when the amplitude of the detected current does not exceed the range of \textcircled{d} even if the first motor and the second motor are simultaneously operated, it can be seen that a problem or an abnormality has occurred in the second motor which is the motor driven at the time point.

Through the sequential accumulation drive, it is determined whether the load current is increased as much as the load added compared with the load current of the previous stage, thereby reducing the judgment error due to the increase in the total current caused by the usage environment of each individual load or the increase in the load current for life.

When such a determination is made, when a ripple is included in a sensing voltage according to a drive current, the comparison may be made using an average voltage of a drive section and the like.

A method of determining the abnormality of a plurality of motors in a case in which the plurality of motors are driven concurrently will be described below.

As described in FIG. 7, it is possible to group a plurality of motors and to detect an amplitude of current of a plurality of groups in a group with one sensor. At this time, since multiple loads are simultaneously driven, a large complex load current flows as shown in operation (c) of FIG. 8.

At this time, the maximum and minimum current values when driving in \textcircled{c} mode are stored in memory based on the composite load current of \textcircled{c} mode. Thereafter, it is possible to determine the abnormality by comparing the maximum and minimum values of the reference current values of the \textcircled{c} mode stored in the system by sensing the current value operated in the \textcircled{c} mode in the initial set warm-up operation or the set self-checking before going to the preparation stage.

Meanwhile, when the load current detected in the \textcircled{c} mode is sensed as being less or larger than the reference current value as in \textcircled{e}, it may be determined that the abnormality occurred in any one of motors in the corresponding group.

If it is determined that the abnormality occurs in any one from among motors in the group, it may be identified as to which motor is abnormal by using the sequential drive method described above or by using the method of FIG. 9 which will be described below.

As described above, a plurality of motors are simultaneously driven and the abnormality of a plurality of motors is determined through the above, and thus, it is possible to determine the abnormality quickly compared with the case where a load current of individual load is identified over several times. In addition, when a group of loads are simultaneously driven, it is possible to drive the entire system in such a way that it is not dangerous to the entire system in consideration of a starting current. In addition, it is possible to separately determine whether there is an abnormality in starting and in constant speed by setting the judgment criteria based on the current increase/decrease at startup and the current increase/decrease at constant speed after startup.

FIG. 9 illustrates a method of determining the abnormality of a plurality of motors in a case in which the plurality of motors are sequentially driven individually.

First, a system may store the load current detection value at the step \textcircled{f} where each of the motors is not operated as 0 or the no load drive current detection value.

Thereafter, it is possible to drive a plurality of motors in a first group one by one individually alone at a specific time point, such as the initial set warm-up drive or the set check-up stage before going to a preparation stage, and compare a drive current 0 under no load or the no load drive detection value \textcircled{f} with a value detected at the time point when individual load is driven alone. In addition, if there is no increase in the load current detection value, it may be determined that the abnormality is present in the corresponding motor or the motor control group or in the assembly.

Meanwhile, such an identification operation may be performed in the initialization process of the image forming apparatus. Specifically, it is possible to monitor the load current detection value during the initialization warm-up of the set and store the monitored load current detection value in a memory based on the load current detection value at the drive control time point of each drive load at the set initialization operation in the normal state. Thereafter, the load current fluctuation in the initial warm-up section of the set is compared based on time or based on a drive control time point per motor. When the load current fluctuation turns out to be less than the current detection value at the time of normal operation, or when there is no change in the current detection at the time when the motor is driven (motor IC abnormality or motor harness mis-assembling), it may be determined that the abnormality in operation of the corresponding motor has occurred. In this case, the fact that the error occurred may be displayed on the display.

In related art motor, etc., the motor control time point and the sensor signal change are not simultaneously checked from a sensor level change due to an instrument drive according to a motor drive and thus, it is not possible to detect the error even though the motor is not normally operated. Even in the case of a portion in which the drive portion error detection is not immediately performed due to such an instrument sensor change, if the above detection method is applied, the drive error of the motor may be detected.

FIG. 11 is a diagram illustrating an operation of not determining that an over current is an abnormality at the initial drive.

Referring to FIG. 11, in a plurality of drive portions or in a system that requires a large load current when driven, there may be a portion where the load current detected in a specific section is excluded from judgment and masked. Thereafter, it is determined whether the corresponding load current is abnormal based on a standard as to the upper and lower limit values of the load current detected in a section where the steady current at constant speed is consumed.

In a case in which the load current becomes larger than normal, the frictional force of the frictional surfaces between the mechanisms may be increased due to the livability, or the deformation of the assembled structure may be a factor. The drive load may be increased by mis-assembling by the operator in the initial assembly or during service of the parts replacement. As described above, when a drive current larger than a normal drive load current is sensed, a UI indicating that the inspection of the corresponding portion is necessary may be displayed, or it may be displayed as a check-up item at a later time.

When the load current becomes less than normal, it may be a case in which only a motor is driven without an instrument load being engaged with the motor due to the abnormality of a coupling portion gear between the drive portion and the instrument, or a detection voltage is not generated since the motor is not driven due to the abnormality of the motor unit, the abnormality of the control portion and the unassembled harness, and the drive current is not generated.

As described above, by storing and managing the load current change in memory and comparing the frequency of problems, such as jamming occurring from the increase/decrease of load on the set or the fixing device applied force error, with the load current change, when it is determined that the cause is the motor or the increase/decrease of instrument load, a message for replacement or inspection of assembly state may be displayed as a UI at a specific time point, or an inspection may be supported in advance by determining that the corresponding portion is likely to generate a problem during servicing.

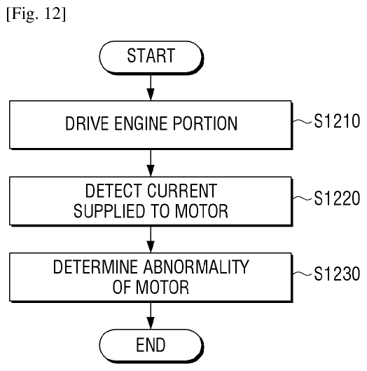

FIG. 12 is a flowchart illustrating a method for image forming, according to an example embodiment.

Referring to FIG. 12, first, a drive command is provided to a motor for starting an engine portion used to perform an image forming job, at operation 51210.

Then, a current amplitude of power provided to the motor is detected at operation S1220. For example, an amplitude of current may be detected using a sensor for detecting an amplitude of current by using a magnetic field of a power line.

Then, it is determined whether the motor is abnormal based on the current amplitude detected after the drive command is provided and a drive command S1230. For example, it may be determined whether the motor is abnormal by comparing the current lower limit value information and current upper limit value information corresponding to the drive command provided to the motor with the detected current magnitude. When the abnormality of the motor is additionally determined, a type of defect may be determined based on the pre-detected current magnitude and the drive command provided to the motor.

When the defect type is determined, an operation relating to the determined defect type may be displayed.

As described above, the image forming method according to the example embodiment may determine whether the motor is abnormal even if a sensor capable of detecting an abnormality in the drive portion is not used. Accordingly, a structure of an image forming apparatus can be further simplified, and a circuit configuration can be made easier and with lower cost.

In addition, the image forming method according to the example embodiment can continuously monitor the change in the current of the motor and can predict the possibility of an abnormality of the apparatus due to the life of the component caused by the increase in the load of the instrument drive gear friction portion or the increase in the coupling load on the assembly. In addition, the image forming method according to the example embodiment may accurately identify in which configuration an error has occurred even if the motor failure occurs, making it easy to fix the failure. The method for image forming as shown in FIG. 12 may be executed on the image forming apparatus 100 having the configuration as shown in FIG. 1 or 2, and may be executed even on an image forming apparatus or a motor control apparatus.

In addition, the above-described image forming method may be realized as at least one execution program to execute the above-described image forming method, and such an execution program may be stored in a non-transient readable recording medium.

A non-transitory computer readable medium may refer to a machine-readable medium or device that stores data semi-permanently and not for a short period of time, such as a register, cache, memory, and the like. In detail, the above-described various applications or programs may be stored in the non-transitory computer readable medium, for example, a compact disc (CD), a digital versatile disc (DVD), a hard disc, a Blu-ray disc, a universal serial bus (USB), a memory card, a read only memory (ROM), and the like, and may be provided.

While the general inventive concept has been shown and described with reference to certain embodiments thereof, it will be understood by those skilled in the art that various changes in form and detail may be made therein without departing from the spirit and principles of the present general inventive concept, the scope of which is defined by the appended claims and their equivalents.

1. An image forming apparatus, comprising:
an engine portion to perform an image forming job;
a motor to drive the engine portion;
a drive circuit to provide power to the motor, and including a sensor to detect a current amplitude of the power provided to the motor; and
a processor to provide a drive command to the motor and to determine whether the motor is abnormal based on the drive command and a current amplitude detected by the sensor after the drive command is provided.

2. The image forming apparatus as claimed in claim 1, further comprising:
a memory to store current lower limit value information and current upper limit value information for each of a plurality of drive commands,
wherein the processor is further to determine whether the motor is abnormal by comparing current lower limit value information and current upper limit value information which correspond to the drive command provided to the motor with the current amplitude detected by the sensor after the drive command is provided.

3. The image forming apparatus as claimed in claim 1, wherein the processor is further to, in response to determining that the motor is abnormal, determine a type of defect based on the drive command provided to the motor and the current amplitude detected by the sensor after the drive command is provided.

4. The image forming apparatus as claimed in claim 3, further comprising:
a display to display information corresponding to the type of defect.

5. The image forming apparatus as claimed in claim 1, wherein the processor is further to determine whether the motor is abnormal based on the current amplitude detected by the sensor a predetermined duration of time after the drive command is provided.

6. The image forming apparatus as claimed in claim 1, wherein
the image forming apparatus includes a plurality of motors,
the sensor is to detect a current amplitude commonly supplied to the plurality of motors, and
the processor is further to determine whether the plurality of motors are abnormal based on a drive command provided to each of the plurality of motors and the current amplitude detected by the sensor after the drive command is provided.

7. The image forming apparatus as claimed in claim 6, wherein the processor is further to sequentially provide the drive command to each of the plurality of motors and to determine whether each of the plurality of motors is abnormal based on the sequentially provided drive command and the current amplitude detected by the sensor after the sequentially provided drive command is provided.

8. The image forming apparatus as claimed in claim 6, wherein the processor is further to simultaneously provide a drive command to the plurality of motors and to determine whether the plurality of motors are abnormal based on whether the current amplitude detected by the sensor after the drive command is provided exceeds a predetermined range.

9. The image forming apparatus as claimed in claim 8, wherein in response to determining the plurality of motors are abnormal, the processor is further to sequentially provide a drive command to each of the plurality of motors and identify which one or more motors among the plurality of motors are abnormal.

10. The image forming apparatus as claimed in claim 6, wherein in response to a print command being received, the processor is further to warm up the engine portion and to determine whether the plurality of motors are abnormal by providing the drive command to the plurality of motors.

11. The image forming apparatus as claimed in claim 1, wherein the sensor is disposed on a power line between an output of a power supply and a power input terminal of the motor, and is to detect the current amplitude based on an electric field on the power line.

12. A method, comprising:
providing a drive command to a motor that drives an engine portion of an image forming apparatus;
detecting a current amplitude of power supplied to the motor; and
determining whether the motor is abnormal based on the drive command and a current amplitude detected after the drive command is provided.

13. The image forming method as claimed in claim 12, wherein the determining comprises determining whether the motor is abnormal by comparing current lower limit value information and current upper limit value information which correspond to the drive command provided to the motor with the current amplitude detected after the drive command is provided.

14. The image forming method as claimed in claim 12, further comprising:
in response to determining that the motor is abnormal, determining a type of defect based on the drive command provided to the motor and the current amplitude detected after the drive command is provided.

15. The image forming method as claimed in claim 12, wherein
the image forming apparatus includes a plurality of motors,
the detecting comprises detecting a current amplitude commonly supplied to the plurality of motors by using a sensor, and
the determining comprises determining whether the plurality of motors are abnormal based on a drive command provided to each of the plurality of motors and the current amplitude detected by the sensor after the drive command is provided.
